(19) United States
(12) Patent Application Publication
(10) Pub. No.: US 2020/0043901 A1
(43) Pub. Date: Feb. 6, 2020

(54) LASER TRANSFER PRINTING FOR MAKING MICRO LED DISPLAY DEVICES AND METHOD

(71) Applicant: Intel Corporation, Santa Clara, CA (US)

(72) Inventors: Khaled AHMED, Anaheim, CA (US); Anup PANCHOLI, Hillsboro, OR (US)

(21) Appl. No.: 16/053,559

(22) Filed: Aug. 2, 2018

(51) Int. Cl. H01L 25/075; H01L 27/12; H01L 33/06; H01L 33/08; H01L 33/24; H01L 33/32; H01L 33/42; H01L 33/46; H01L 33/62; B41M 5/24; B41F 16/00

(52) U.S. Cl. CPC H01L 25/0753; H01L 27/1214; H01L 33/06; H01L 33/08; H01L 33/24; H01L 33/32; H01L 2933/0066; H01L 33/46; H01L 33/62; B41M 5/24; B41F 16/00; H01L 2933/0016; H01L 2933/0025; H01L 33/42

(57) ABSTRACT

Embodiments disclosed herein include micro-light emitting diode (LED) displays and methods of forming such micro-LED displays. In an embodiment, a micro-light emitting diode (LED) display panel includes a display backplane substrate having a dielectric layer. In an embodiment, a plurality of electrical contacts are positioned below a first surface of the dielectric layer. In an embodiment a plurality of micro-LED pixel elements, are affixed to corresponding ones of the plurality of contacts.

### TECHNICAL FIELD

Embodiments of the disclosure are in the field of micro-LED displays.

### BACKGROUND

Displays having micro-scale light-emitting diodes (LEDs) are known as micro-LED, mLED, and μLED. As the name implies, micro-LED displays have arrays of micro-LEDs forming the individual pixel elements.

A pixel may be a minute area of illumination on a display screen, one of many from which an image is composed. In other words, pixels may be small discrete elements that together constitute an image as on a display. These primarily square or rectangular-shaped units may be the smallest item of information in an image. Pixels are normally arranged in a two-dimensional (2D) matrix, and are represented using dots, squares, rectangles, or other shapes. Pixels may be the basic building blocks of a display or digital image and with geometric coordinates.

### BRIEF DESCRIPTION OF THE DRAWINGS

FIG. 1 is a schematic illustration of a display architecture, in accordance with an embodiment of the present disclosure.

FIG. 2 is a schematic illustration of a micro-light emitting diode (LED) display architecture, in accordance with an embodiment of the present disclosure.

FIGS. 3A-3F illustrate cross-sectional views of a method of transferring pixel elements from a silicon wafer to a display backplane, in accordance with an embodiment of the present disclosure.

FIG. 4A is a cross-sectional illustration of a display backplane with a mirror below the pixel elements, in accordance with an embodiment of the present disclosure.

FIG. 4B is a cross-sectional illustration of a display backplane with a mirror between sidewalls of the pixel elements and the display backplane, in accordance with an embodiment of the present disclosure.

FIG. 4C is a cross-sectional illustration of a display backplane with non-vertical cavity sidewalls, in accordance with an embodiment of the present disclosure.

FIG. 5 is a flow diagram illustrating a micro-LED display production process, in accordance with an embodiment of the present disclosure

FIG. 6A is a cross-sectional illustration of a schematic of a display aligner and release chamber, in accordance with an embodiment of the present disclosure.

FIG. 6B is a perspective view illustration of a display aligner and release chamber configured to accommodate a plurality of donor wafers, in accordance with an embodiment of the present disclosure.

FIG. 7 is a cross-sectional illustration of a red-green-blue chip (an RGB chip) with three nanowire LEDs, in accordance with an embodiment of the present disclosure.

FIG. 8A is a cross-sectional illustration of a GaN nanowire based LED highlighting certain layers of the LED, in accordance with an embodiment of the present disclosure.

FIG. 8B is a cross-sectional illustration of a micro-LED composed of multiple nanowire LEDs, in accordance with an embodiment of the present disclosure.

FIG. 8C a cross-sectional illustration of a GaN nanopyramid or micropyramid based LED highlighting certain layers of the LED, in accordance with an embodiment of the present disclosure.

FIG. 8D is a cross-sectional illustration of a GaN axial nanowire based LED highlighting certain layers of the LED, in accordance with an embodiment of the present disclosure.

FIG. 9 is an electronic device having a display, in accordance with embodiments of the present disclosure.

### DESCRIPTION OF THE EMBODIMENTS

A micro light-emitting diode (LED) display, its fabrication and assembly are described. In the following description, numerous specific details are set forth, such as specific material and structural regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

One or more embodiments described herein are directed to devices and methods for micro LED assembly. In an embodiment, a device and method for fabricating full-color micro light emitting diode (μLED) displays by micro transfer assembly are described. Micro LED displays promise 3×-5× less power compared to organic LED (OLED) displays. The difference would result in a savings in battery life in mobile devices (e.g., notebook and converged mobility) and can enhance user experience. In an embodiment, micro LED displays described herein consume two-fold less power compared to organic LED (OLED) displays. Such a reduction in power consumption may provide an additional approximately 8 hours of battery life. Such a platform may even outperform platforms based on low power consumption central processing units (CPUs). Embodiments described herein may be associated with one or more advantages such as, but not limited to, high manufacturing yield, high manufacturing throughput (display per hour), and applicability for displays with a diagonal dimension ranging from 2 inches or greater. In certain embodiments described herein displays may be fabricated on large glass substrates (e.g., Gen 5, Gen 6, Gen 7, Gen 8, Gen 9, Gen 10, or larger).

To provide further context, displays based on inorganic micro LEDs (μLEDs) have attracted increasing attention for applications in emerging portable electronics and wearable computers such as head-mounted displays and wristwatches. Micro LEDs are typically first manufactured on Sapphire or silicon wafers (for example) and then transferred onto a display backplane glass substrate where on which active matrix thin-film transistors have been manufactured. The target acceptable defect density after such a transfer is approximately 1-2 ppm. This low defect density requirement may be achieved by transferring two micro LEDs for each color (red, green and blue), a so-called “redundancy strategy.” However, transferring more micro LEDs for redundancy may result in higher manufacturing cost.

In accordance with an embodiment of the present disclosure, addressing both cost and defectivity requirements, monolithic red, green and blue pixels are manufactured on a wafer and then transferred, as opposed to transferring individual micro LEDs with different colors from three separate source wafers sequentially. As described herein, source wafers are fabricated having individual red green blue (RGB) pixels (chips) thereon. Equipment and process technologies are then implemented to transfer micro LEDs from a source wafer directly to a target display backplane substrate. Thus, it is to be appreciated that typically three colors are transferred at the same time. It is not necessarily the case that “one RGB pixel” is transferred. Rather, it may be the case that one “whole” pixel is transferred. In another case, red, green, and blue micro LEDs are spaced appropriately on the source wafer such that when they are transferred to the display backplane, they will land on pre-designated contact pads that may be separated by half of the pixel pitch or one quarter of the pixel pitch or other similar large enough spacing to prevent color bleeding.

To provide further context, a state-of-the-art approach involves transfer with a stamp. For example, a stamp picks from the source wafer and the transfers to a target substrate where micro LED devices are assembled with driving electronics to provide a display. The approach, however, requires the need for pick up, bond, and release mechanisms. The approach is typically slow and expensive, and requires unique tooling.

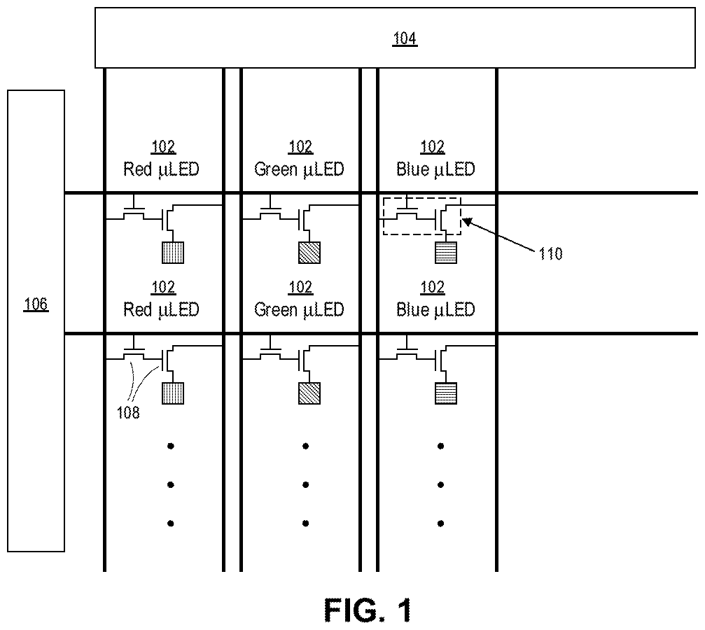

FIG. 1 is a schematic illustration of a display architecture, in accordance with an embodiment of the present disclosure. Referring to FIG. 1, micro LEDs 102 are arranged in a matrix. The micro LEDs are driven through “Data Driver” 104 and “Scan Driver” 106 chips. Thin film transistors 108 are used to make “pixel driver circuits” 110 for each micro LED. In an embodiment, the micro LEDs are fabricated on a silicon wafer then transferred to a glass substrate called “backplane” where the “pixel driver circuits” 110 have been fabricated using thin film transistors.

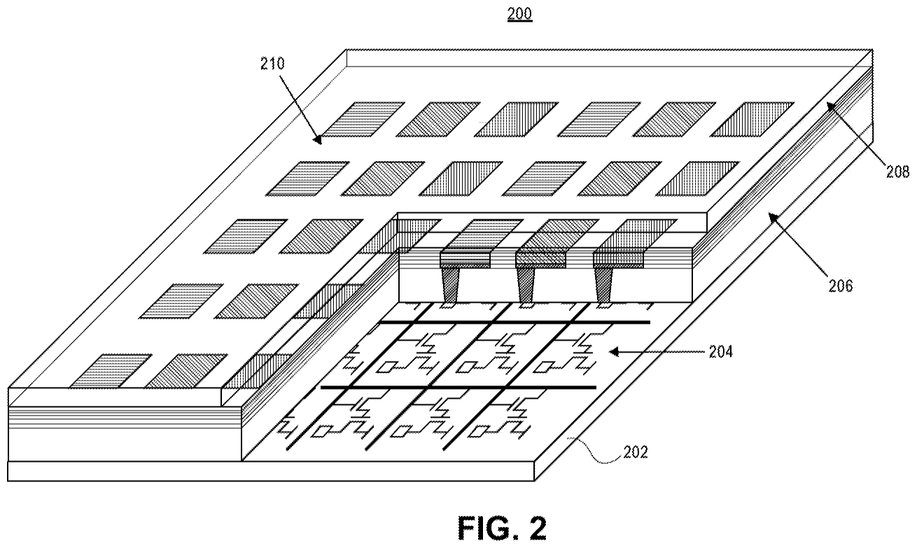

As an exemplary display architecture, FIG. 2 illustrates a schematic of micro LED display architecture, in accordance with an embodiment of the present disclosure. Referring to FIG. 2, a micro LED display 200 includes a backplane 202 having pixel circuits 204 thereon. An insulator 206 is over the pixel circuits 204. Micro LED layers 208 are included over the insulator 206. A transparent electrode 210 is over the micro LED layers 208.

In a first aspect, in accordance with an embodiment of the present disclosure, direct transfer from source to target is used to fabricate micro LED displays. Micro LED devices are fabricated on a source wafer and then transferred directly to a target display backplane where the micro LED devices are assembled with driving electronics to provide a display. In an embodiment, the release of the micro LEDs that are grown and attached to a silicon wafer is performed using “selective laser release.” The selectivity at small pitch (e.g., less than 2 micron) is accomplished by using pulsed laser irradiation of the portions of a release layer over which the micro LEDs are formed. In an embodiment, the pulsed irradiation of the release layer results in ablation, delamination and/or weakening of the interface between the release layer and the wafer and/or the interface between micro LED and release layer upon heating by femtosecond or picosecond pulses of laser irradiation. In a particular embodiment, the coefficient of thermal expansion (CTE) mismatch between release layer and micro LED and/or the release layer and the wafer will likely result in large stress at these interfaces causing release of micro LEDs from the silicon wafer.

Femtosecond and picosecond laser pulses have been shown to be ideal tools for micro structuring of solid targets. The main features of femtosecond and picosecond pulse laser ablation are: (i) the existence of a sharp fluence threshold for material removal that is much lower than for nanosecond (and longer) laser pulses; (ii) rapid energy deposition and fast ablation without heat- and shock-affected zones; and (iii) the possibility of controllable ablation and production of high-quality structures in any solid material. In general, when many laser shots are required for material processing, the transversal size of the produced structures is limited by the diffraction limit of the optical system.

By using laser pulses of a duration in the range of 10 femtoseconds to 1000 picoseconds, extremely precise machining has been achieved with essentially no heat or shock affected zone. Because the pulses are so short, there is negligible thermal conduction beyond the region removed resulting in negligible thermal stress or shock to the material beyond approximately 0.1-1 micron (dependent upon the particular material) from the laser machined surface. Due to the short duration, the high intensity (e.g., greater than 10¹² W/cm²) associated with the interaction converts the material directly from the solid-state into an ionized plasma. Since there is negligible heating beyond the depth of material removed, the composition of the remaining material is unaffected by the laser machining process. This enables high precision machining of alloys and even pure metals with no change in grain structure.

Higher power and ultrashort pulse (e.g., less that 100 ps) laser output may raise the release layer structure material temperature more quickly and supply enough energy to exceed the required latent heat of vaporization of the release layer material, therefore resulting in direct vaporization of most or all of the irradiated portions of the release layer. This direct vaporization is ideal since it will result in little chance of re-deposition of the “removed” release layer material back onto the surrounding area of the substrate.

In an embodiment, infrared laser wavelength may be small enough (e.g., approximately 1.3 μm-1.5 μm) to provide better laser beam focusability (and hence smaller laser output spots), and maximize the absorbance of high conductivity release layer structures. The infrared laser may have a wavelength long enough so that the silicon substrate will be transparent to the infrared radiation.

While femtosecond and picosecond pulses minimize (or eliminate) heat transfer away from the desired regions, some embodiments may also include a thermal isolation layer (e.g., dielectric) between adjacent micro LEDs. In a particular embodiment, when one micro LED is released by ablating (via laser irradiation) of the “release layer,” the adjacent micro LED are not to be impacted. By implementing thermal isolation, impact to neighboring micro-LEDs will be eliminated and will not be inadvertently released even when longer duration laser pulses (e.g., greater than 100 picoseconds) are used. A release layer located underneath only the desired micro-LED for transfer is ablated and the integrity of neighboring dies remains intact for a next transfer. Implementing such an approach may be advantageous by improving transfer yield significantly, which reduces cost of manufacturing.

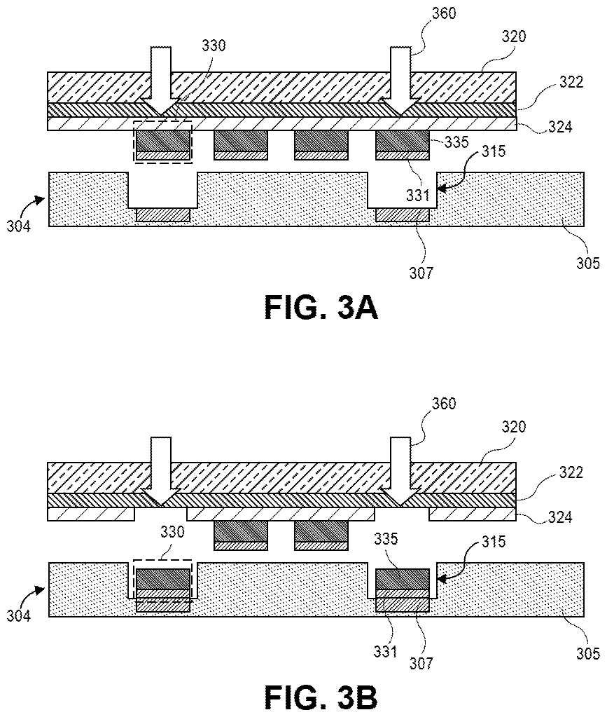

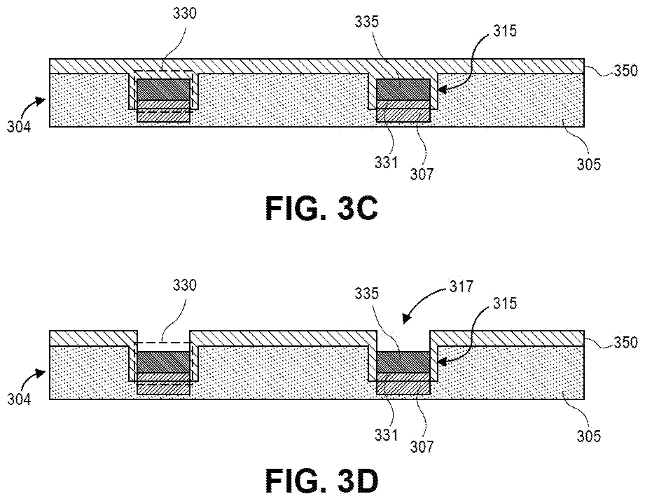

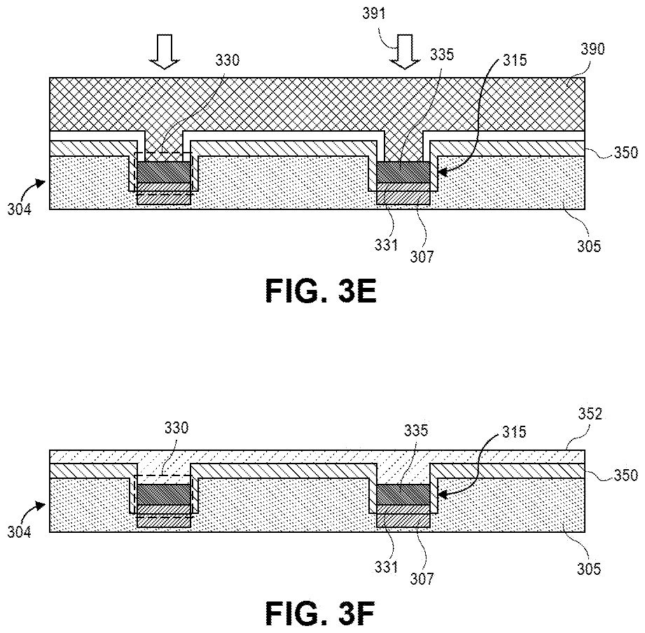

FIGS. 3A-3F illustrate cross-sectional views of a method of transferring pixel elements or RGB chips from a silicon wafer to a display backplane, in accordance with an embodiment of the present disclosure. It is to be appreciated that, as contemplated for embodiments described herein, typically, a plurality of micro LEDs with different colors that have been grown on a single wafer monolithically is transferred to the display backplane. The scope is thus not limited to transferring “RGB chips”. As used herein, “pixel element” may refer to a sub-pixel (e.g., a red LED chip, a blue LED chip, or a green LED chip) or an entire pixel (e.g., a group of RGB chips).

Referring to FIG. 3A, a silicon wafer 320 having micro LED pixel elements 330 thereon is aligned with electrical contacts 307 of a backplane 304, such as a display thin film transistor (TFT) backplane. The alignment may be performed using infrared imaging, optical, or mechanical approaches. In an embodiment, the backplane 304 may comprise a first dielectric layer 305. For example, the first dielectric layer 305 may be silicon dioxide (SiO₂) or the like. In an embodiment, the electrical contacts 307 may be positioned in the bottom of a cavity 315 formed into a first surface of the dielectric layer 305. However, it is to be appreciated that embodiments are not limited to the use of cavities, and the electrical contacts 307 may also be formed on the first surface (i.e., the top surface) of the dielectric layer 305. In an embodiment, the electrical contacts 307 may be electrically coupled to pixel circuits (not shown) of the backplane 304.

In an embodiment, the LED pixel elements 330 may comprise an active device 335 and a metal contact 331. The active device may be in direct contact with a release layer 324. In an embodiment, the release layer 324 may be a material that becomes more volatile than the LED pixel elements 330 when irradiated with laser energy. For example, the release layer may be amorphous silicon or a transition metal nitride (e.g., HfN, TiN, or the like). In an embodiment, the release layer 324 may have a thickness that is less than 100 nm. In a particular embodiment, the release layer 324 may have a thickness that is between approximately 20 nm and 50 nm.

In an embodiment, the release layer 324 may be separated from the silicon wafer 320 by a buffer layer 322. The buffer layer 322 may be any suitable material or stack of materials, such as AlN. In an embodiment the buffer layer 322 may have a thickness that is less than 100 nm. In an embodiment, the buffer layer 322 may have a thickness that is approximately 50 nm.

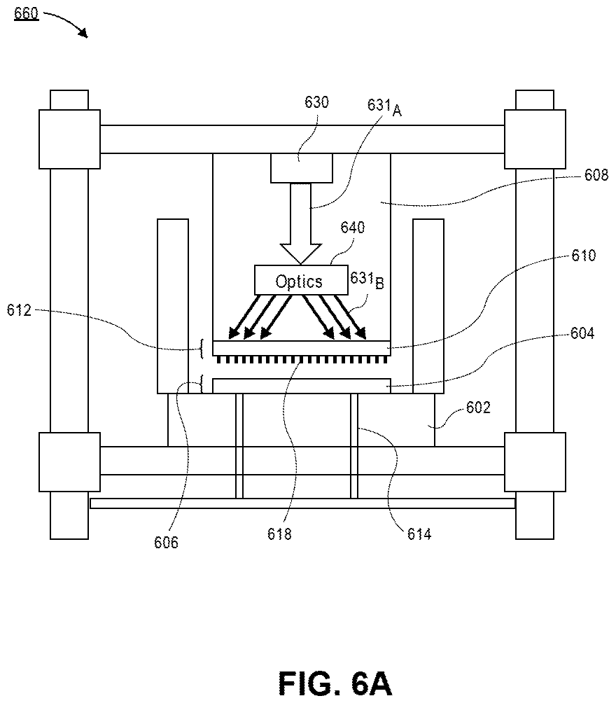

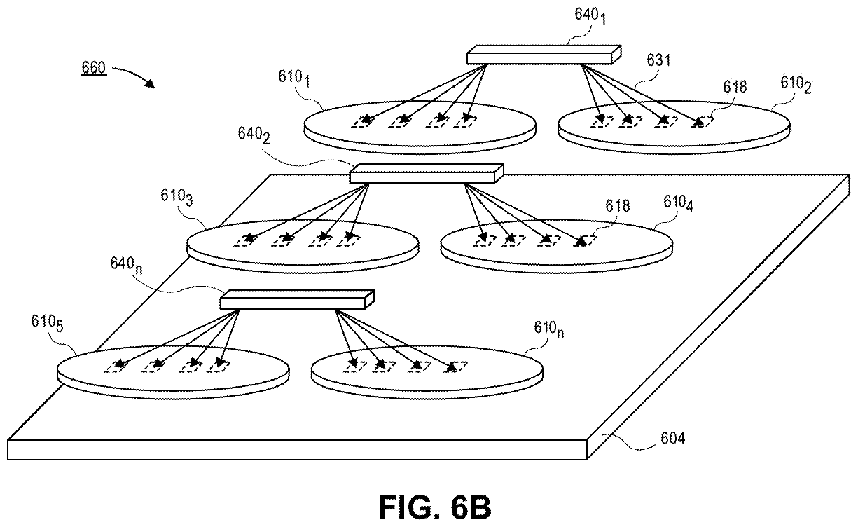

In an embodiment, after the silicon wafer 320 is aligned with the backplane 304, portions of the release layer 324 may be irradiated with radiation 360 (e.g., IR radiation) from a laser source (not shown). Particularly, the portions of the release layer 324 contacting the LED pixel elements 330 may be irradiated with radiation 360. In some embodiments, a single source of the radiation 360 may be used, and an optics module (described in greater detail below with respect to FIG. 6A) may be used to distribute the radiation 360 to the desired locations. In some embodiments, the radiation 360 may be distributed towards some of the LED pixel elements 330 on the silicon wafer 320. For example, the radiation 360 is distributed to two of the LED pixel elements 330 in FIG. 3A. However, it is to be appreciated that radiation 360 may be distributed to some or all of the LED pixel elements 330 on the silicon wafer 320. For example, all of the LED pixel elements 330 on a silicon wafer 320 may be released with a single processing operation in some embodiments.

While the use of picosecond or femtosecond pulses minimizes the spread of thermal energy in the release layer 324, in some embodiments further protection may be desired. In accordance with another embodiment of the present disclosure, a thermal isolation material, such as silicon dioxide, silicon nitride, aluminum oxide, or similar materials, is patterned in between the pixel elements. Upon IR laser ablation of targeted release layer 324, the thermal isolation barrier prevents heat dissipation to the release layer over neighboring LED pixel elements 330, and hence prevents unwarranted release.

In an embodiment the radiation 360 may be pulsed. The pulse durations may be picosecond or femtosecond pulses. For example, the pulse durations may be between 10 femtoseconds and 1000 picoseconds. In an embodiment, the wavelength of the radiation 360 may be such that the radiation 360 passes through the silicon wafer 320. That is, the silicon wafer 320 may be transparent to the radiation 360. In an embodiment, the radiation is preferentially absorbed by the release layer 324. As such, the release layer 324 is weakened, ablated, vaporized, or the like.

Referring now to FIG. 3B, a cross-sectional illustration after the LED pixel elements 330 are released from the silicon wafer 320 is shown, in accordance with an embodiment. As illustrated, the portions of the release layer 324 have been removed (e.g., with the laser radiation 360) and the LED pixel elements 330 drop into the cavities 315. As shown, the metal contacts 331 rest on respective ones of the electrical contacts of the backplane 304. While the portions of the release layer 324 are shown as being completely removed, it is to be appreciated that this may not always be the case. For example, residual portions of the release layer 324 may remain on the buffer layer 322 or on portions of the active device 335.

In the illustrated embodiment, the released LED pixel elements 330 are shown as being entirely below the top surface of the dielectric layer 305. That is, the cavity 315 may have a depth that is greater than a Z-height of the LED pixel elements 330. However, in some embodiments, the portions of the LED pixel elements 330 may extend above a top surface of the dielectric layer 305. That is, the cavity 315 may have a depth that is less than a Z-height of the LED pixel elements 330.

Furthermore, while each cavity 315 is shown as accommodating a single LED pixel element 330, embodiments are not limited to such embodiments. For example, a plurality of LED pixel elements 330 may be placed in each cavity 315. In an exemplary embodiment, the cavities 315 may be trenches that extend into and out of the plane of FIG. 3B and which accommodate a plurality of LED pixel elements 330.

In the illustrated embodiment of FIG. 3B, it is to be appreciated that the LED pixel elements 330 are not affixed to the electrical contacts 307. Instead, the metal contact 331 of the LED pixel elements 330 are resting on the electrical contacts 307 and are not mechanically held in place.

Referring now to FIG. 3C, a cross-sectional illustration of the backplane 304 after a second dielectric layer 350 is deposited is shown, in accordance with an embodiment. In an embodiment, the second dielectric layer 350 is formed over the LED pixel elements 330 and mechanically affixes the metal contact 331 to the electrical contact 307 of the backplane 304. The second dielectric layer 350 may fill the cavities 315. As such, the second dielectric layer 350 may be formed over sidewalls and a top surface of the LED pixel elements 330.

In an embodiment, the second dielectric layer 350 is a different material than the first dielectric layer 305. In such embodiments, the refractive index of the second dielectric layer 350 may be lower than a refractive index of the first dielectric layer 305. Such an embodiment may be beneficial in reducing total internal reflections of light emitted by the LED pixel elements 330, and therefore, improve efficiency of the system. However, it is to be appreciated that additional embodiments may include a second dielectric layer 350 that is the same material as the first dielectric layer 305.

Referring now to FIG. 3D, a cross-sectional illustration of the backplane 304 after openings 317 are formed over the LED pixel elements 330 is shown, in accordance with an embodiment. In an embodiment, the openings 317 may be formed with any suitable process, such as etching, milling, laser drilling, or the like. In an embodiment, the openings 317 expose a top surface of the active device 335. While an entire top surface of the active devices 335 are shown as being exposed, it is to be appreciated that only a portion of the top surface of the active devices 335 may be exposed in some embodiments. Furthermore, it is to be appreciated that the second dielectric layer 350 may remain along sidewalls of the active devices 335 in order to keep the metal contact 331 affixed to the electrical contact 307 of the backplane 304.

Referring now to FIG. 3E, a cross-sectional illustration of a pressure plate 390 applying pressure (as indicated by arrows 391) to the LED pixel elements 330 is shown, in accordance with an embodiment. In an embodiment, the pressure plate 390 may apply force in order to aid in the bonding of the metal contacts 331 to the electrical contacts 307 of the backplane 304. In some embodiments, the bonding may be implemented with the addition of heat. For example, pressure plate 390 may be a part of a thermal compression bonding tool. In one embodiment, the thermal compression bonding is performed at a temperature in the range of 25° C. to 430° C., and at a pressure in the range of 1-2 MPa. In an embodiment, the bonding process may result in a metallurgical bond being formed between the metal contacts 331 and the electrical contacts 307.

It is noted that the thermal compression bonding process is implemented after the LED pixel elements 330 are released from the silicon wafer 320. That is, the transfer of the LED pixel elements 330 to the backplane 304 comprises a release operation followed by a bonding operation. Prior disclosed technologies rely on a bonding operation that is subsequently followed by a release operation.

Furthermore, while a bonding operation is disclosed in FIG. 3E, it is to be appreciated that a bonding operation is not necessary in all embodiments. For example, the second dielectric layer 350 may provide sufficient mechanical coupling between the metal contacts 331 and the electrical contacts 307 of the backplane 304 to provide reliable devices.

Referring now to FIG. 3F, a cross-sectional illustration after a common cathode 352 is deposited over the backplane 304 is shown, in accordance with an embodiment. In an embodiment, the common cathode 352 may be any transparent conductive material, such as a transparent conductive oxide (TCO). For example, the common cathode 352 may be an indium tin oxide (ITO).

In embodiments where not all of the LED pixel elements 330 are released from the silicon wafer 320 simultaneously, a second backplane may be aligned to the silicon wafer 320 after the first backplane 304 is removed from the alignment tool. In such an embodiment, a second backplane may be brought in close proximity of the silicon source wafer but with a misalignment that is equivalent to the pixel element pitch on the silicon wafer 320 in order to release a second set of pixel elements from silicon wafer 320 onto the second backplane. The alignment may be performed using infrared imaging, optical, or mechanical approaches.

It is to be appreciated that the process flow described above with respect to FIGS. 3A-3F is exemplary in nature and embodiments may comprise additional or fewer processing operations. Additionally, the backplane 304 in FIGS. 3A-3F is shown with a simplified geometry. In accordance with additional embodiments, the backplane 304 may comprise additional features that may improve the efficiency of the device.

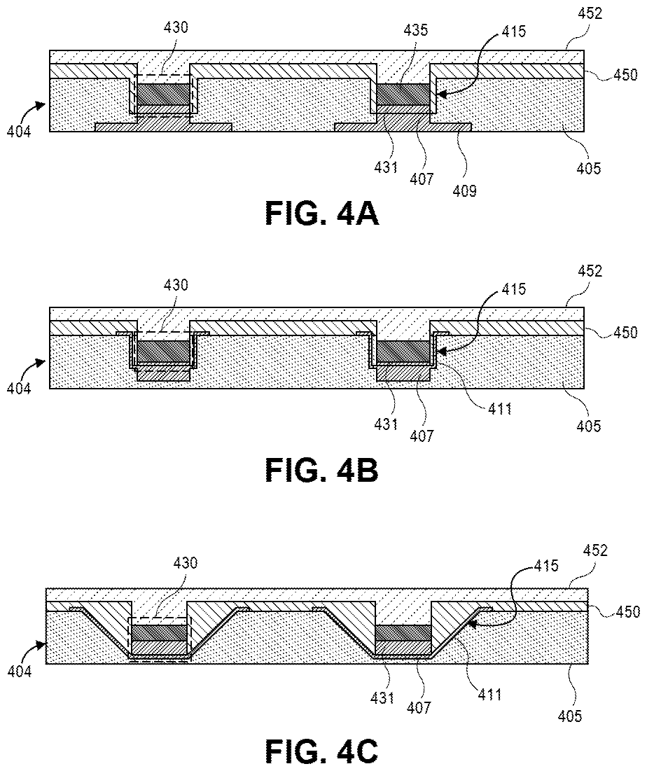

One such additional feature is shown in FIG. 4A. The backplane 404 in FIG. 4A may be substantially similar to the backplane in FIGS. 3A-3F, with the exception that a mirror 409 is formed below the cavity 415. The mirror 409 may be the same material as the electrical contact 407 or the mirror 409 may be a different material. For example, the mirror may be chosen from a material that is tuned to reflect the wavelength emitted by the LED pixel element 430 positioned above the mirror 409.

In another embodiment shown in FIG. 4B, the sidewalls of the cavity 415 may comprise a mirror coating 411. In some embodiments, the mirror coating 411 may also extend over a portion of the top surface of the first dielectric layer 405. In an embodiment, the sidewalls of the active device 435 may be separated from the sidewall of the cavity 415 by a portion of the second dielectric layer 450 and by the mirror coating 411. In an embodiment, the mirror coating 411 may be the same material as the electrical contact 407 or the mirror coating 411 may be a different material.

In yet another embodiment, the sidewalls of the cavity 415 may have a tapered profile, as shown in FIG. 4C. In some embodiments, the tapered sidewalls of the cavity 415 may have a mirror coating 411 in order to improve light extraction from the LED pixel element 430.

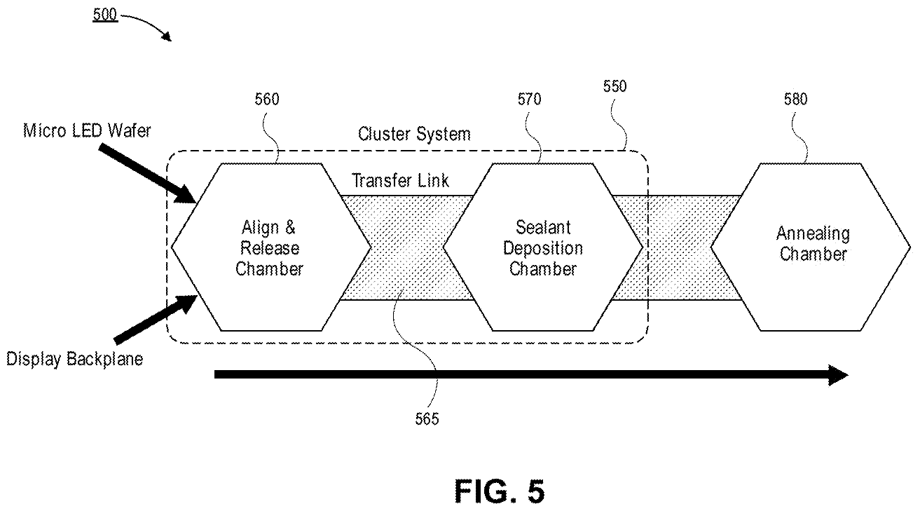

While the process flow described above with respect to FIGS. 3A-3F may be implemented with any suitable processing equipment, another aspect of embodiments of the present disclosure include a processing tool that may be used to fabricate LED backplanes. FIG. 5 is a schematic illustration of a processing line 500 that may be used in some embodiments.

In an embodiment, process line 500 may include a cluster system 550. The cluster system 550 may include any number of chambers and transfer links between the chambers. For example, a first chamber 560 may be connected to a second chamber 570 by a transfer link 565. In an embodiment, the first chamber 560 may be an align and release chamber and the second chamber 570 may be a sealant deposition chamber.

In an embodiment, the align and release chamber 560 may receive a micro LED wafer (e.g., a silicon wafer 320 with a plurality of LED pixel elements 330, such as described above) and a display backplane (e.g., a backplane 304 with cavities 315 formed into a first dielectric layer 305, such as described above). The align and release chamber 360 may then align the micro LED wafer to the display backplane and release the pixel elements formed on the micro LED wafer onto the display backplane (e.g., similar to the process described above with respect to FIGS. 3A and 3B).

After the pixel elements are released onto the display backplane, the cluster system 550 may deliver the display backplane to the sealant deposition chamber 570 via transfer link 565. In the sealant deposition chamber 570, a second dielectric layer may be deposited over the pixel elements (e.g., similar to the second dielectric layer 350 being deposited in FIG. 3C and/or the TCO being deposited in FIG. 3F). At this point, the pixel elements are sealed and affixed to the display backplane. As such, they may be removed from the cluster system 550 and delivered to subsequent processing tools in the line 500. For example, the display backplane may be delivered to an annealing chamber 580.

While a cluster system 550 with a first chamber 560 and a second chamber 570 is shown, it is to be appreciated that the any number of processing tools used to implement the process of forming a display backplane (e.g., such as the process described with respect to FIGS. 3A-3F) may be integrated into a cluster tool. Additional embodiments may include a plurality of distinct processing tools that are used to assemble the display backplane.

In another aspect of embodiments of the present disclosure, an aligner and release chamber for directly transferring pixel elements from a silicon wafer to a display backplane is described. An example of such a processing chamber is described with respect to the cross-sectional view of a schematic of a processing tool 660 illustrated in FIG. 6A.

Referring to FIG. 6A, a processing tool 660 includes a first support 602 for holding a display backplane substrate 604 in a first position 606. A second support 608 is for holding a silicon wafer 610 in a second position 612. The second position 612 is over the first position 606. In one embodiment, a piston 614 is coupled to the first support 602. The piston 614 is for moving the display backplane substrate 604 from the first position 606 toward the second position 612. The first support 602 may also be configured to provide lateral displacement of the display backplane substrate 604. In an embodiment, the second support 608 may also be configured to provide lateral and vertical displacement of the silicon wafer 610. In an embodiment, the alignment of the display backplane substrate 604 relative to the silicon wafer 610 may be performed using infrared imaging, optical, or mechanical approaches. The processing tool may be provided with a vacuum chamber (or any controlled atmosphere).

In an embodiment, the processing tool 660 may comprise a laser source 630 for emitting radiation 631A (e.g., IR radiation). An optics module 640 may be located between the laser source 630 and the display backplane substrate 604. In an embodiment, the optics module 640 may comprise optics components (e.g., splitters, mirrors, prisms, lenses, etc.) to distribute and focus a plurality of optical pathways 631E between the optics module 640 and the display backplane substrate 604. While six optical pathways 631E are shown in FIG. 6A, it is to be appreciated that any number of optical pathways 631E may be used. In some embodiments, the number of optical pathways 631E may be equal to the number of LED pixel elements 618 attached to the silicon wafer 610. The optical pathways 631E provide a focused spot of laser radiation (e.g., femtosecond or nanosecond pulses of laser radiation) that ablates (or otherwise deteriorates) a release layer (not shown) that secures the LED pixel elements 618 to the silicon wafer 610. After the release layer is ablated, the LED pixel elements 618 are released to drop onto the underlying display backplane substrate 604, as described in greater detail above with respect to FIGS. 3A-3F.

In some embodiments, the processing tool 660 may be suitable for transferring LED pixel elements 618 on one silicon wafer 610 at a time. That is, there may be a one-to-one ratio of silicon wafers 610 to display backplane substrates 604 in the processing tool at any given time. In some embodiments, each display backplane substrate 604 may receive LED pixel elements 618 from more than one silicon wafer 610. For example, a first silicon wafer 610 with a first set of LED pixel elements 618 may be aligned with the display backplane substrate 604 and the first set of LED pixel elements 618 may be released onto the display backplane substrate 604. Thereafter, the first silicon wafer 610 may be removed from the processing tool 660, and a second silicon wafer 610 with a second set of LED pixel elements 618 may be aligned with the display backplane substrate 604 and the second set of LED pixel elements 618 may be released onto the display backplane substrate 604.

Furthermore, it is to be appreciated that embodiments are scalable and may accommodate a plurality of silicon wafers in parallel. An example of such a processing tool is shown in FIG. 6B.

Referring now to FIG. 6B, a perspective illustration of portions of a processing tool 660 is shown, in accordance with an additional embodiment. In FIG. 6B, some structural features (e.g., supports, chamber walls, etc.) are omitted to not obscure embodiments described herein. In the illustrated embodiment, a single display backplane substrate 604 and a plurality of silicon wafers 610₁-610n are within the processing tool 660. While six silicon wafers 610 are shown, it is to be appreciated that any number of silicon wafers 610 may be processed in parallel. Accordingly, the size of the display backplane substrate 604 is highly scalable. For example, embodiments may include display backplane substrates 604 that are any generation of glass substrate size (e.g., generation 5, generation 6, generation 7, generation 8, generation 9, generation 10, or beyond).

In an embodiment, processing tool 660 may also comprise a plurality of optics modules 640₁-640n. While each optics module 640 is illustrated as providing optical pathways 631 to the release layer above LED pixel elements 618 on two separate silicon wafers 610, it is to be appreciated that embodiments are not limited to such configurations. For example, the optics modules 640 and silicon wafers 610 may have a one-to-one ratio, a one-to-three ratio, or any other desired ratio. While not shown, each optics module modules 640 may be paired with a different source laser.

Since the transfer of LED pixel elements 618 on a plurality of silicon wafers 610 to a single display backplane substrate 604 may be implemented substantially in parallel, the throughput (i.e., displays per hour) is incredibly high, even for extremely large displays.

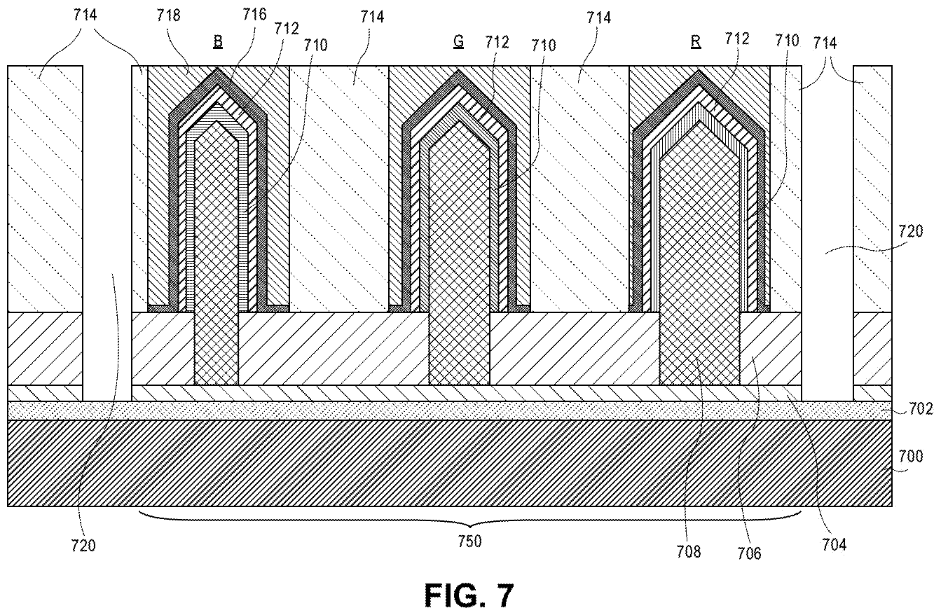

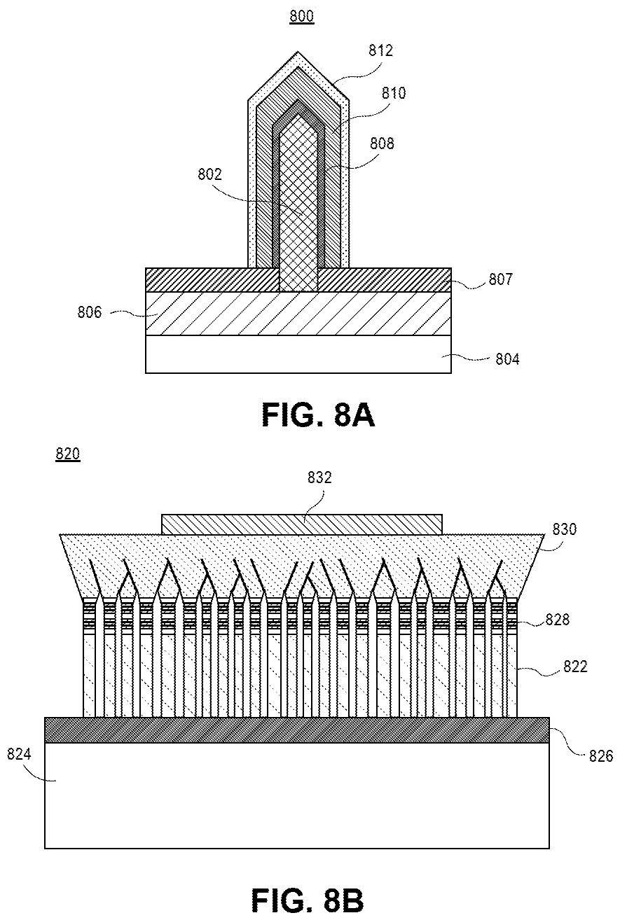

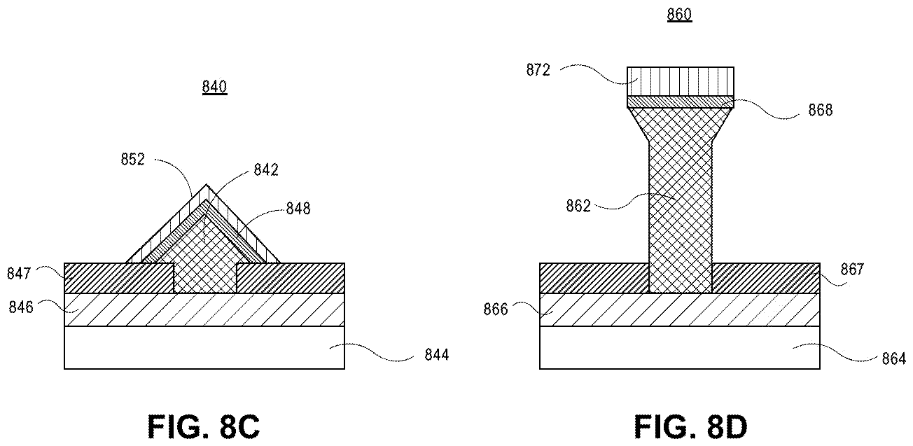

Up until this point, the pixel elements have been described as generic blocks. It is to be appreciated that the scope of embodiments described herein are not limited to any particular micro LED structure. However, FIGS. 7 and 8A-8D provide exemplary illustrations of some micro LEDs that may be used in conjunction with embodiments disclosed herein.

FIG. 7 illustrates a cross-sectional view of a red green blue chip (an RGB chip) with three nanowire LEDs, in accordance with an embodiment of the present disclosure. Referring to FIG. 7, although shown as three different color micro-LEDs across (e.g., blue, green, red from left-right), the three are shown in this manner for illustrative purposes only. It is to be appreciated that for a pixel such as a 2×2 pixel element, only two micro LEDs would be viewable for a given cross-section. It is to be appreciated that a variety of arrangements of micro LEDs may be suitable to make a single pixel. In one embodiment, three micro LEDs are arranged side-by-side, as depicted in FIG. 7. In another embodiment, four micro LEDs are arranged a 2×2 arrangement. In another embodiment, nine micro LEDs are arranged a 3×3 arrangement (three red micro LEDs, three green micro LEDs, and three blue micro LEDs), etc. It is to be appreciated that a micro LED is composed of an array of nanowire LEDs. The number of nanowire LEDs per one micro LEDs is at least one. For example, a 10 μm×10 μm micro LED may be composed of 90 nanowire LEDs connected in parallel to emit light of a specific color. It is further to be appreciated that, with respect to FIG. 7, the micro LEDs are represented by one nanowire each for illustrative purposes. This in general is not the case. Typically, one micro LED will be composed of more than one nanowire LED. Also, in FIG. 7, one example arrangement is shown. That is, the three colors are adjacent to each other. However, in some cases, the micro LEDs of different colors are separated on the source wafer by a distance that may be half of the display pixel pitch, for example.

With reference again to FIG. 7, in a particular embodiment, a source micro LED wafer 700 (such as a silicon wafer) has “RGB Chips” monolithically grown thereon. The silicon wafer 700 is first coated with an aluminum nitride (AlN) buffer layer 702, e.g., having a thickness of approximately 50 nanometers. The AlN buffer layer 702 may have a bandgap of about 6 eV and may be transparent to infrared radiation. A metal-based nucleation layer (MNL) 704 is then deposited on the AlN buffer layer 702. The MNL 704 may have a thickness in the range of 30-100 nm and may be crystalline or polycrystalline. In an embodiment, the MNL 704 may be used as the “release layer” described above. For example, the MNL 704 may be a material that preferentially absorbs the laser radiation in order to separate the RGB chips from the silicon wafer 700. In an embodiment, the MNL 704 may be a transition metal nitride, such as HfN, TiN, or the like. A silicon nitride mask 706 is then deposited on the MNL 704. Lithography may then be used to open apertures in the silicon nitride mask 706 mask with diameters carefully chosen to accommodate the subsequent formation of LEDs that emit red, green, and blue colors. N-type GaN nanowire cores are then grown, e.g., by metal organic chemical vapor deposition (MOCVD), as seeded from the MNL 704. The nanowire cores may have diameters in the range 50 nm to 250 nm.

Referring again to FIG. 7, indium gallium nitride (InGaN) shells 710 are grown around the GaN cores 708, e.g., using MOCVD. The amount of indium in the InGaN shells 710 depends on the GaN core diameter. In an embodiment, smaller core diameter result in the growth of InGaN shells with smaller indium content. Larger core diameters result in the growth of InGaN shells with larger indium content. For blue (B) color emission, the indium content is approximately 20%. For green (G) color emission, the indium content is approximately 30%. For red (R) color emission, the indium content is approximately 40%. A p-type GaN cladding layer 712 may then be formed around the InGaN shells 710, e.g., using MOCVD. The core-shell nanowires are then covered by an insulating material layer 714, e.g., a silicon oxide (SiOx) layer. A lithography and etch may then be used to expose the p-GaN cladding layers 712 for all color core-shell nanowire structures. Atomic layer deposition may then be used to conformally deposit a metal layer 716 on the p-GaN cladding layers 712. A metal fill process may then be performed to fill in contact metals 718 for the micro LED structures.

Referring more generally to FIG. 7 a semiconductor structure includes a silicon wafer 700 and plurality of LED pixel elements 750. Each of the LED pixel elements 750 includes a first color nanowire LED, a second color nanowire LED (the second color different than the first color), and a pair of third color nanowire LEDs (the third color different than the first and second colors). A continuous insulating material layer 714 is laterally surrounding the first color nanowire LED, the second color nanowire LED, and the pair of third color nanowire LEDs. Adjacent pixel elements are separated from one another by a trench 720 between corresponding continuous insulating material layers 714. It is to be appreciated that more than three colors may be fabricated. For example, structures may be fabricated for red, green, yellow or blue emission. In another example, structures may be fabricated for red, orange, green, or blue emission.

In an embodiment, for each of the LED pixel elements 750, the first color is red, the second color is green, and the third color is blue. In another embodiment, for each of the LED pixel elements 750, the first color is red, the second color is blue, and the third color is green. In another embodiment, for each of the LED pixel elements 750, the first color is blue, the second color is green, and the third color is red. In an embodiment, for each of the LED pixel elements 750, the first color nanowire LED, the second color nanowire LED, and the pair of third color nanowire LEDs have a 2×2 arrangement. In another embodiment, a structure referred to as “monolithic blue and green only” may be fabricated. In such a case, three times as many blue micro LEDs as the green micro LEDs are fabricated. Then, after transfer of the blue and greed micro LEDs to the display backplane (at one shot of transfer), quantum dots are added on some of the blue micro LEDs to convert that blue to red color.

In an embodiment, upon fabrication of a micro-LED wafer, in order to fabricate a micro-LED based display, a direct transfer method is used in which micro-LEDs from source wafers are aligned to a target display backplane with the assistance of precise alignment, and released from the source wafer with a selective release using IR laser radiation by means of selectively ablating the MNL in the source wafer.

FIG. 8A illustrates a cross-sectional view of a GaN nanowire based LED highlighting certain layers of the LED, in accordance with an embodiment of the present disclosure. In the exemplary embodiment of FIG. 8A, an LED 800 includes an n-type GaN nanowire 802 above a substrate 804, which may be a silicon substrate. An intervening release layer 806 has an opened mask layer 807 thereon. An active layer 808/810 (which may be a single active layer replacing 808/810) is included on the n-type GaN nanowire 802. In a particular embodiment, an In_{0.2}Ga_{0.8}N shell “buffer” layer 808 is included on the n-type GaN nanowire 802, and an active In_{0.4}Ga_{0.6}N layer 810 is included on the In_{0.2}Ga_{0.8}N shell “buffer” layer 808. In one such embodiment, the In_{0.4}Ga_{0.6}N layer 810 emits red color (e.g., having a wavelength in the range of 610-630 nanometers). A p-GaN or p-ZnO cladding layer 812 is included on the active layer 808/810.

In another such embodiment, following the fabrication of an ordered n-type InₓGa₁₋ₓN nanowire array with x in the range of 0.15-0.25, the remainder of the LED structure is grown radially around the nanowires. An In_{y}Ga_{1-y}N layer is on the InₓGa₁₋ₓN nanowires (and may be included in a set of In_{y}Ga_{1-y}N/GaN multi-quantum well (MQW) active layers) with y in the range of 0.4-0.45. An undoped GaN layer and/or AlGaN electron blocking layer may be included as the next outer layer. Finally, a p-type GaN (or p-type ZnO) cladding layer may be included.

FIG. 8B illustrates a cross-sectional view of a micro-LED composed of multiple nanowire LEDs, in accordance with an embodiment of the present disclosure. In the exemplary embodiment of FIG. 8B, a micro-LED 820 includes an n-GaN nano-column 822 above a substrate 824, which may be a silicon substrate. An intervening release layer 826 is included between the n-GaN nano-column 822 and the substrate 824. An InGaN/GaN multi-quantum well device (MQD) stack 828 is included on the n-GaN nano-column 822. A p-GaN layer 830 is on the multi-quantum well device (MQD) stack 828. A transparent p-electrode 832 is included on the p-GaN layer 830.

It is to be appreciated that foundational geometries other than the above described nanowires may be used for LED fabrication. For example, in another embodiment, FIG. 8C illustrates a cross-sectional view of a GaN nanopyramid or micropyramid based LED highlighting certain layers of the LED, in accordance with an embodiment of the present disclosure. In the exemplary embodiment of FIG. 8C, an LED 840 includes an n-GaN nanopyramid 842 above a substrate 844, which may be a silicon substrate. An intervening release layer 846 has an opened mask layer 847 thereon. An InGaN layer 848 is included on the GaN nanopyramid 842. A p-GaN or p-ZnO cladding layer 852 is included on the InGaN layer 848. It is to be appreciated that a micro LED may be composed of multiple nanopyramids connected in parallel. For example, a 5 μm×5 μm micro LED may be composed of 20 nanopyramids.

In another embodiment, FIG. 8D illustrates a cross-sectional view of a GaN axial nanowire based LED highlighting certain layers of the LED, in accordance with an embodiment of the present disclosure. In the exemplary embodiment of FIG. 8D, an LED 860 includes an n-GaN axial nanowire 862 above a substrate 864, which may be a silicon substrate. An intervening release layer 866 has an opened mask layer 867 thereon. An InGaN layer 868 is included on the GaN axial nanowire 862. A p-GaN or p-ZnO cladding layer 872 is included on the InGaN layer 868.

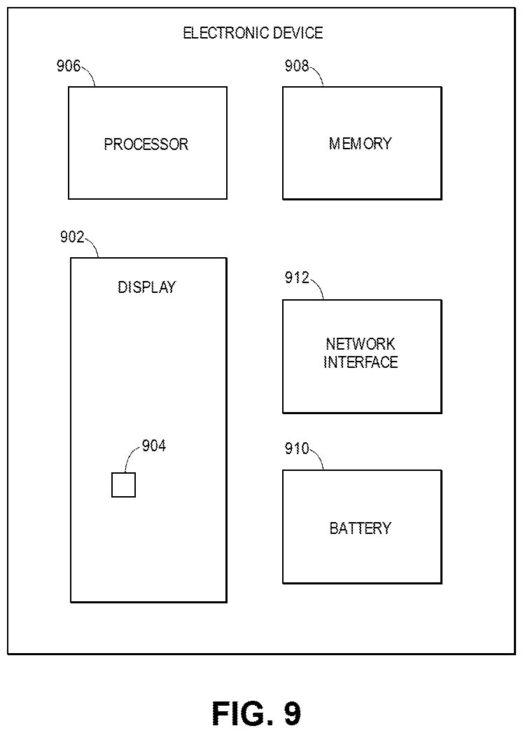

FIG. 9 is an electronic device having a display, in accordance with embodiments of the present disclosure. Referring to FIG. 9, an electronic device 900 has a display or display panel 902 with a micro-structure 904. The display may also have glass layers and other layers, circuitry, and so forth. The display panel 902 may be a micro-LED display panel. As should be apparent, only one microstructure 904 is depicted for clarity, though a display panel 902 will have an array or arrays of microstructures including nanowire LEDs.

The electronic device 900 may be a mobile device such as smartphone, tablet, notebook, smartwatch, and so forth. The electronic device 900 may be a computing device, stand-alone display, television, display monitor, vehicle computer display, the like. Indeed, the electronic device 900 may generally be any electronic device having a display or display panel.

The electronic device 900 may include a processor 906 (e.g., a central processing unit or CPU) and memory 908. The memory 908 may include volatile memory and nonvolatile memory. The processor 906 or other controller, along with executable code store in the memory 908, may provide for touchscreen control of the display and well as for other features and actions of the electronic device 900.

In addition, the electronic device 900 may include a battery 910 that powers the electronic device including the display panel 902. The device 900 may also include a network interface 912 to provide for wired or wireless coupling of the electronic to a network or the internet. Wireless protocols may include Wi-Fi (e.g., via an access point or AP), Wireless Direct®, Bluetooth®, and the like. Lastly, as is apparent, the electronic device 900 may include additional components including circuitry and other components.

Thus, embodiments described herein include micro light-emitting diode (LED) fabrication and assembly.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### Example 1

a micro-light emitting diode (LED) display panel, comprising: a display backplane substrate having a dielectric layer; a plurality of electrical contacts below a first surface of the dielectric layer; and a plurality of micro-LED pixel elements, wherein each of the pixel elements is affixed to corresponding ones of the plurality of contacts.

### Example 2

the micro-LED display panel of Example 1, further comprising: a plurality of cavities formed into the first surface of the dielectric layer, wherein the plurality of electrical contacts are each positioned in corresponding ones of the plurality of cavities.

### Example 3

the micro-LED display panel of Example 1 or Example 2, wherein each of the plurality of micro-LED pixel elements comprises a width that is less than a width of the cavity in which they are positioned.

### Example 4

the micro-LED display panel of Examples 1-3, wherein a second dielectric layer is disposed over the first surface of the dielectric layer, and wherein the second dielectric layer separates sidewall surfaces of the micro-LED pixel elements and a sidewall surface of the cavity.

### Example 5

the micro-LED display panel of Examples 1-4, wherein the plurality of micro-LED pixel elements are mechanically affixed to the plurality of electrical contacts by the second dielectric layer.

### Example 6

the micro-LED display panel of Examples 1-5, further comprising: a plurality of mirrors, wherein each of the plurality of mirrors is positioned below corresponding ones of the plurality of cavities.

### Example 7

the micro-LED display panel of Examples 1-6, further comprising: a plurality of a mirrors, wherein each of the plurality of mirrors is positioned along sidewall surfaces of corresponding ones of the plurality of cavities.

### Example 8

the micro-LED display panel of Examples 1-7, wherein the sidewall surfaces of the plurality of cavities are non-vertical.

### Example 9

the micro-LED display panel of Examples 1-8, wherein the plurality of micro-LED pixel elements are affixed to respective electrical contacts with an annealing process.

### Example 10

the micro-LED display panel of Examples 1-9, wherein the plurality of micro-LED pixel elements is a plurality of nanowire-based LED pixel elements.

### Example 11

the micro-LED display panel of Examples 1-10, wherein the plurality of nanowire-based LED pixel elements comprises GaN nanowires.

### Example 12

the method of manufacturing a micro-light emitting diode (LED) display panel, the method comprising: positioning a silicon substrate above a display backplane, wherein the silicon substrate comprises an LED pixel element and a release layer between the silicon substrate and the LED pixel element, and wherein the display backplane comprises a cavity and an electrical contact in the cavity; aligning the silicon substrate with the display backplane substrate, wherein the LED pixel element is over and above the electrical contact in the cavity; and ablating a portion of the release layer, wherein ablating the portion of the release layer separates the LED pixel element from the silicon substrate, and wherein the LED pixel element falls into the cavity.

### Example 13

the method of Example 12, wherein ablating the portion of the release layer comprises irradiating the portion of the release layer with an IR laser.

### Example 14

the method of Example 12 or Example 13, wherein the IR laser is pulsed with pulses having a duration between 10 femtoseconds and 1000 picoseconds.

### Example 15

the method of Examples 12-14, wherein the laser energy us between 10 mJ/cm² and 10 J/cm².

### Example 16

the method of Examples 12-15, wherein LED pixel element comprises a metal contact, and wherein the metal contact is in contact with the electrical contact in the cavity after the LED pixel element is released from the silicon substrate.

### Example 17

the method of Examples 12-16, further comprising: affixing the metal contact of the LED pixel element to the electrical contact in the cavity by depositing a second dielectric layer over the LED pixel element.

### Example 18

the method of Examples 12-17, further comprising: forming an opening through the second dielectric layer to expose a surface of the LED pixel element; and depositing a transparent conductive oxide over the exposed surface of the LED pixel element.

### Example 19

the method of Examples 12-18, further comprising: annealing the display backplane to form a metallurgical bond between the metal contact of the LED pixel element and the electrical contact of the display backplane.

### Example 20

the method of Examples 12-19, wherein the release layer is amorphous silicon or a transition metal nitride.

### Example 21

the method of Examples 12-20, wherein the LED pixel element is a nanowire-based LED pixel element.

### Example 22

a processing chamber, comprising: a chamber; a first support in the chamber for supporting a receiving substrate; a second support in the chamber for supporting a donor substrate, wherein the donor substrate comprises a plurality of light emitting diode (LED) pixel elements attached to the donor substrate by a release layer; a laser source; and an optics module, wherein the optics module receives laser radiation from the laser source and distributes the laser radiation to a plurality of locations on the donor substrate supported by the second support.

### Example 23

the processing chamber of Example 22, further comprising: a plurality of laser sources, and a plurality of optics modules, wherein each optics module is optically coupled to corresponding ones of the plurality of laser sources, and wherein the second support supports a plurality of donor substrates.

### Example 24

the processing chamber of Example 22 or Example 23, wherein the first support is capable of supporting generation 5 glass substrates or larger.

### Example 25

the processing chamber of Examples 22-24, wherein the optics module distributes the laser radiation to a number of locations on the donor substrate that is equal to the number of LED pixel elements attached to the donor substrate.

What is claimed is:

1. A micro-light emitting diode (LED) display panel, comprising:
a display backplane substrate having a dielectric layer;
a plurality of electrical contacts below a first surface of the dielectric layer; and
a plurality of micro-LED pixel elements, wherein each of the pixel elements is affixed to corresponding ones of the plurality of contacts.

2. The micro-LED display panel of claim 1, further comprising:
a plurality of cavities formed into the first surface of the dielectric layer, wherein the plurality of electrical contacts are each positioned in corresponding ones of the plurality of cavities.

3. The micro-LED display panel of claim 2, wherein each of the plurality of micro-LED pixel elements comprises a width that is less than a width of the cavity in which they are positioned.

4. The micro-LED display panel of claim 3, wherein a second dielectric layer is disposed over the first surface of the dielectric layer, and wherein the second dielectric layer separates sidewall surfaces of the micro-LED pixel elements and a sidewall surface of the cavity.

5. The micro-LED display panel of claim 4, wherein the plurality of micro-LED pixel elements are mechanically affixed to the plurality of electrical contacts by the second dielectric layer.

6. The micro-LED display panel of claim 2, further comprising:
a plurality of mirrors, wherein each of the plurality of mirrors is positioned below corresponding ones of the plurality of cavities.

7. The micro-LED display panel of claim 2, further comprising:
a plurality of a mirrors, wherein each of the plurality of mirrors is positioned along sidewall surfaces of corresponding ones of the plurality of cavities.

8. The micro-LED display panel of claim 7, wherein the sidewall surfaces of the plurality of cavities are non-vertical.

9. The micro-LED display panel of claim 1, wherein the plurality of micro-LED pixel elements are affixed to respective electrical contacts with an annealing process.

10. The micro-LED display panel of claim 1, wherein the plurality of micro-LED pixel elements is a plurality of nanowire-based LED pixel elements.

11. The micro-LED display panel of claim 1, wherein the plurality of nanowire-based LED pixel elements comprises GaN nanowires.

12. A method of manufacturing a micro-light emitting diode (LED) display panel, the method comprising:
positioning a silicon substrate above a display backplane, wherein the silicon substrate comprises an LED pixel element and a release layer between the silicon substrate and the LED pixel element, and wherein the display backplane comprises a cavity and an electrical contact in the cavity;
aligning the silicon substrate with the display backplane substrate, wherein the LED pixel element is over and above the electrical contact in the cavity; and
ablating a portion of the release layer, wherein ablating the portion of the release layer separates the LED pixel element from the silicon substrate, and wherein the LED pixel element falls into the cavity.

13. The method of claim 12, wherein ablating the portion of the release layer comprises irradiating the portion of the release layer with an IR laser.

14. The method of claim 13, wherein the IR laser is pulsed with pulses having a duration between 10 femtoseconds and 1000 picoseconds.

15. The method of claim 14, wherein the laser energy us between 10 mJ/cm² and 10 J/cm².

16. The method of claim 12, wherein LED pixel element comprises a metal contact, and wherein the metal contact is in contact with the electrical contact in the cavity after the LED pixel element is released from the silicon substrate.

17. The method of claim 16, further comprising:
affixing the metal contact of the LED pixel element to the electrical contact in the cavity by depositing a second dielectric layer over the LED pixel element.

18. The method of claim 17, further comprising:
forming an opening through the second dielectric layer to expose a surface of the LED pixel element; and
depositing a transparent conductive oxide over the exposed surface of the LED pixel element.

19. The method of claim 17, further comprising:
annealing the display backplane to form a metallurgical bond between the metal contact of the LED pixel element and the electrical contact of the display backplane.

20. The method of claim 12, wherein the release layer is amorphous silicon or a transition metal nitride.

21. The method of claim 12, wherein the LED pixel element is a nanowire-based LED pixel element.

22. A processing chamber, comprising:
a chamber;
a first support in the chamber for supporting a receiving substrate;
a second support in the chamber for supporting a donor substrate, wherein the donor substrate comprises a plurality of light emitting diode (LED) pixel elements attached to the donor substrate by a release layer;
a laser source; and
an optics module, wherein the optics module receives laser radiation from the laser source and distributes the laser radiation to a plurality of locations on the donor substrate supported by the second support.

23. The processing chamber of claim 22, further comprising:
a plurality of laser sources, and a plurality of optics modules, wherein each optics module is optically coupled to corresponding ones of the plurality of laser sources, and wherein the second support supports a plurality of donor substrates.

24. The processing chamber of claim 23, wherein the first support is capable of supporting generation 5 glass substrates or larger.

25. The processing chamber of claim 22, wherein the optics module distributes the laser radiation to a number of locations on the donor substrate that is equal to the number of LED pixel elements attached to the donor substrate.
